(19) United States
(12) Patent Application Publication
(10) Pub. No.: US 2026/0059812 A1
(43) Pub. Date: Feb. 26, 2026

(54) TRENCH BASED SEMICONDUCTOR DEVICES WITH EPITAXIALLY REGROWN LAYERS

(71) Applicant: Wolfspeed, Inc., Durham, NC (US)

(72) Inventors: Madankumar Sampath, Durham, NC (US); Rahul R. Potera, Apex, NC (US); Sei-Hyung Ryu, Cary, NC (US)

(21) Appl. No.: 18/810,026

(22) Filed: Aug. 20, 2024

(51) Int. Cl. H01L 29/10; H01L 21/02; H01L 21/04; H01L 29/16; H01L 29/66; H01L 29/808

(52) U.S. Cl. CPC H10D 62/343; H01L 21/02529; H01L 21/046; H01L 21/0475; H10D 12/031; H10D 30/831; H10D 62/8325

(57) ABSTRACT

A silicon carbide semiconductor device includes a drift layer, a channel layer on the drift layer, the channel layer having a first conductivity type, a trench in the channel layer and a mesa adjacent to the trench, and a gate region within the trench. The gate region has a second conductivity type opposite the first conductivity type, and the gate region includes an epitaxially regrown layer. A method of forming a silicon carbide semiconductor device includes providing a drift layer, forming a channel layer on the drift layer, the channel layer having a first conductivity type, etching the channel layer to form a trench in the channel layer and a mesa adjacent to the trench, and epitaxially regrowing a gate region within the trench, wherein the gate region has a second conductivity type opposite the first conductivity type.

### TECHNICAL FIELD

The present disclosure relates to semiconductor devices and, more particularly, to trench-based vertical semiconductor devices.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate contacts, and one or more gate buses and/or gate contacts that electrically connect the gate pad to the gate contacts. The gate contacts are disposed adjacent the respective channel regions. Power JFETs are typically normally-on devices, meaning that a JFET conducts current when a voltage of 0 volts is applied to the gate structure.

### SUMMARY

A silicon carbide semiconductor device according to some embodiments includes a drift layer, a channel layer on the drift layer, the channel layer having a first conductivity type, a trench in the channel layer and a mesa adjacent to the trench, and a gate region within the trench. The gate region has a second conductivity type opposite the first conductivity type, and the gate region includes an epitaxially regrown layer.

The silicon carbide semiconductor device may further include a gate contact region in the channel layer beneath the trench, wherein the gate contact region may have a second conductivity type opposite the first conductivity type, wherein the gate region may be in contact with the gate contact region.

The silicon carbide semiconductor device may further include a gate ohmic contact on the gate contact region, and a dielectric spacer on a sidewall of the gate region facing the trench.

The gate region may have a doping concentration of about 1E18 cm−3 to about 1E21 cm−3. In some embodiments, the gate region may have a doping concentration of about 5E18 cm−3 to about 1E20 cm−3, in some embodiments about 1E19 cm−3.

A product of a thickness of the gate region and a doping concentration of the gate region may be about 1E14 cm−2 to 1E16 cm−2. In some embodiments, the product of a thickness of the gate region and a doping concentration of the gate region may be greater than about 1E14 cm−2, and in some embodiments, the product of a thickness of the gate region and a doping concentration of the gate region may be about 5E14 cm−2 to 5E15 cm−2.

The gate region may have a thickness of about 0.1 microns to 2 microns. In some embodiments, the gate region may have a thickness of about 0.3 microns to 1.5 microns, and in some embodiments a thickness of about 0.5 microns to 1 micron.

The silicon carbide semiconductor device may be a junction field effect transistor device.

The silicon carbide semiconductor device may further include a source layer in the mesa on the channel layer, wherein the source layer includes an epitaxially regrown layer of silicon carbide.

The epitaxially regrown layer may be on a sidewall of the trench.

A method of forming a silicon carbide semiconductor device according to some embodiments includes providing a drift layer, forming a channel layer on the drift layer, the channel layer having a first conductivity type, etching the channel layer to form a trench in the channel layer and a mesa adjacent to the trench, and epitaxially regrowing a gate region within the trench, wherein the gate region has a second conductivity type opposite the first conductivity type.

The gate region may be on a sidewall of the trench.

The method may further include, after epitaxially regrowing the gate region, implanting second conductivity type dopant ions into the trench to form a gate contact region beneath the trench, wherein the gate contact region contacts the gate region.

The second conductivity type dopant ions are implanted into the mesa and the trench, and the method may further include, after implanting the second conductivity type dopant ions, etching a top portion of the mesa.

The method may further include, after implanting the second conductivity type dopant ions, depositing an oxide layer in the trench, and planarizing the oxide layer.

The method may further include, after etching the top portion of the mesa, implanting second conductivity type ions into the mesa.

The method may further include epitaxially regrowing a source layer on the channel layer.

A silicon carbide semiconductor device according to some embodiments includes a silicon carbide layer including a trench therein, and an epitaxially regrown region within the trench.

The epitaxially regrown region may include a gate region on a sidewall of the trench.

The silicon carbide layer may include a drift layer, a channel layer on the drift layer and a source layer on the channel layer, wherein the drift layer, the channel layer and the source layer have a first conductivity type and the gate region has a second conductivity type opposite the first conductivity type.

The source layer may be epitaxially regrown layer.

A silicon carbide semiconductor device according to some embodiments includes a drift layer, a channel layer on the drift layer, the channel layer having a first conductivity type, a trench in the channel layer and a mesa adjacent to the trench, a gate region within the trench, wherein the gate region has a second conductivity type opposite the first conductivity type, and wherein the gate region includes an epitaxially regrown layer, and a source layer on the channel layer, wherein the source layer has the first conductivity type and includes an epitaxially regrown layer.

A product of a thickness of the gate region and a doping concentration of the gate region may be greater than about 1E14 cm−2. In some embodiments, the product of a thickness of the gate region and a doping concentration of the gate region is about 5E14 cm−2 to 5E15 cm−2.

The gate region may have a thickness of about 0.1 microns to 2 microns.

A method of forming a silicon carbide semiconductor device according to some embodiments includes providing a drift layer, forming a channel layer on the drift layer, the channel layer having a first conductivity type, etching the channel layer to form a trench in the channel layer and a mesa adjacent to the trench, epitaxially regrowing a first semiconductor layer in the trench and on an upper surface of the mesa, the first layer having the first conductivity type, and epitaxially regrowing a second semiconductor layer on the first layer, the second layer having a second conductivity type opposite the first conductivity type.

The method may further include, after epitaxially regrowing the second semiconductor layer, removing portions of the second semiconductor layer from the upper surface of the mesa.

The method may further include, forming a sacrificial dielectric layer in the trench, and implanting first conductivity type dopant ions into the mesa to form a source region in the mesa.

The method may further include, after epitaxially regrowing the second semiconductor layer, implanting second conductivity type dopant ions into the trench to form a gate contact region in the trench.

A silicon carbide semiconductor device according to some embodiments includes a drift layer, a channel layer on the drift layer, the channel layer having a first conductivity type, a trench in the channel layer and a mesa adjacent to the trench, a first epitaxially regrown region in the trench, the first epitaxially regrown region having a first conductivity type, and a second epitaxially regrown region on the first epitaxially regrown region, the second epitaxially regrown region having a second conductivity type opposite the first conductivity type.

The silicon carbide semiconductor device may further include a gate contact region in the channel layer beneath the trench, wherein the gate contact region has the second conductivity type, wherein the gate region is in contact with the second epitaxially regrown region.

The silicon carbide semiconductor device may further include a gate ohmic contact on the gate contact region, and a dielectric spacer on a sidewall of the second epitaxially regrown region facing the trench.

### BRIEF DESCRIPTION OF DRAWINGS

FIG. 1 illustrates a cell of a vertical JFET semiconductor device.

FIGS. 2A, 2B and 3 illustrate some operations for forming the device 10 shown in FIG. 1.

FIGS. 4A-4H illustrate operations for forming a vertical semiconductor device according to some embodiments.

FIGS. 5A-5F illustrate operations for forming a vertical semiconductor device according to further embodiments.

FIGS. 6A-6D illustrate operations for forming a vertical semiconductor device according to further embodiments.

FIG. 7 illustrates operations for forming a vertical semiconductor device according to some embodiments.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected”or “directly coupled”to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices that include mesas and trenches, such as vertical MOSFETs, insulated gate bipolar transistors (IGBTs) and other types of devices.

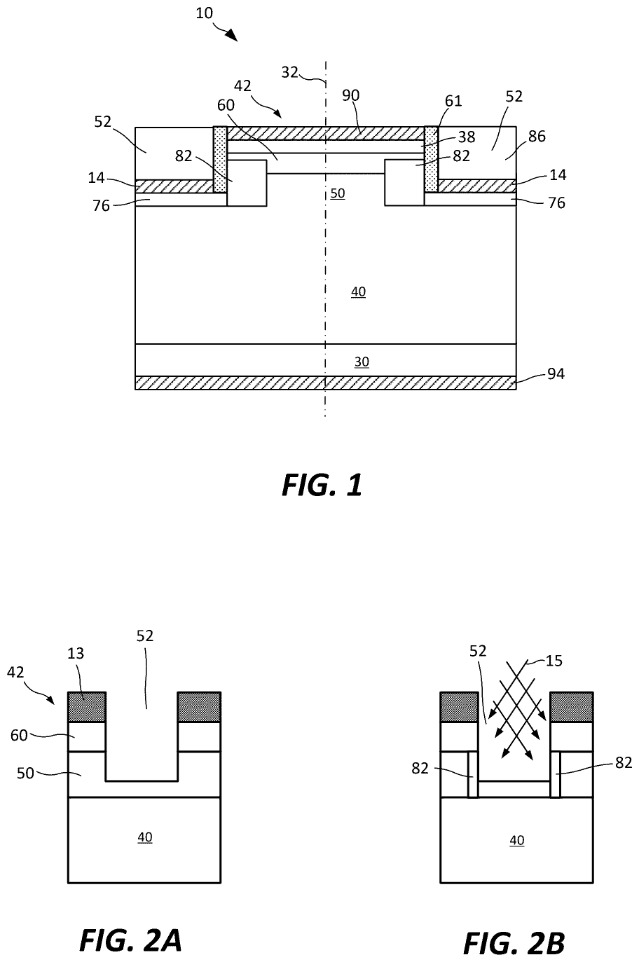

An n-channel vertical JFET structure 10 is shown in FIG. 1. The vertical JFET structure 1 includes an n+ silicon carbide substrate 30 on which an n-silicon carbide drift layer 40 is formed. An n-type silicon carbide channel layer 50 is on the drift layer 40, and an n+ silicon carbide source layer 60 is on the channel layer 50. An n++ silicon carbide source contact layer 38 is on the n+ source layer 60. A drain ohmic contact 94 is on the substrate 30, and a source ohmic contact 90 is on the source contact layer 38. The channel layer 50, source layer 60 and source contact layer 38 are provided as part of a mesa stripe 42 above the drift layer 40. Trenches 52 are formed in the structure 10 adjacent the mesa stripe 42.

A p-type gate region 82 is provided as part of the mesa stripe 42 adjacent the channel layer 50. The p-type gate region 82 may have a high doping concentration, such as a doping concentration greater than 1E19 cm−3. Accordingly, the p-type gate region 82 may be described as having a p+ doping concentration.

A p-type gate contact region 76 is provided adjacent the gate region 82, and a gate ohmic contact, or gate finger, 14 is formed on the gate contact region 76 in the trenches 52 on opposite sides of the mesa stripe 42. The p-type gate contact region 76 may have a doping concentration greater than that of the p-type gate region 82, and thus may be described as having a p++ doping concentration.

To form the gate finger 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 43 is formed in the trenches 52 on the gate finger 14 and the gate contact region 76. The insulation layer 43 may be formed, for example, from silicon oxide. In some embodiments, the insulation layer 43 may be a borophosphosilicate glass (BPSG), which is a type of silicate glass that includes additives of both boron and phosphorus. Oxide/nitride spacer layers 61 are provided on sidewalls of the mesa stripe 42.

The vertical JFET unit cell structure 10 is symmetrical about the axis 32 and includes two gate regions 82 as part of the mesa stripe 42 on opposite sides of the channel layer 50.

The channel layer 50 of the vertical JFET structure 10 is formed within the mesa stripe 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) V_{GS} is applied to the gate regions 82. When no voltage is applied to the gate region 82, charge carriers can flow freely from the source layer 60 through the channel layer 50 and the drift layer 40 to the substrate 30.

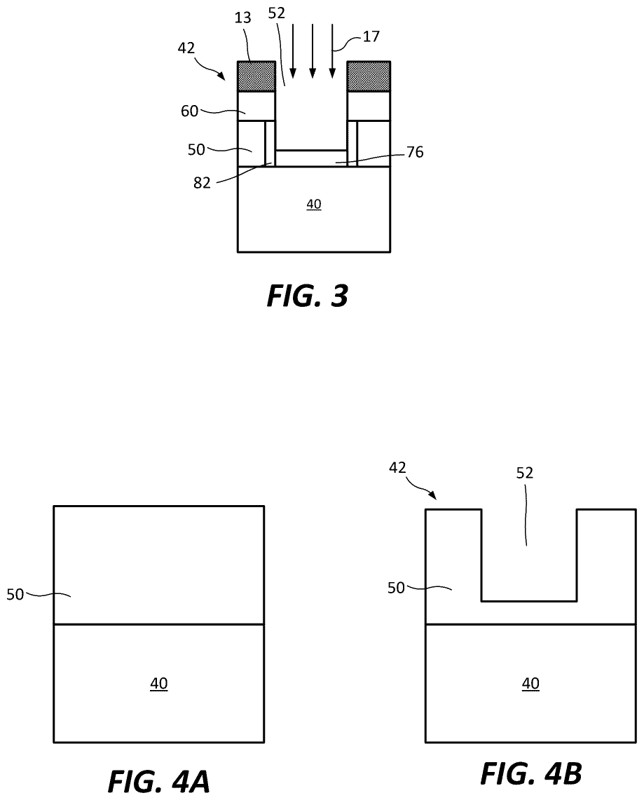

FIGS. 2A, 2B and 3 illustrate some operations for forming the device 10 shown in FIG. 1. In particular referring to FIG. 2A, after formation of the channel layer 50 and the source layer 60 on the drift layer 40, an oxide mask 13 is formed on the structure and a trench 52 is etched in the semiconductor layers to define respective mesas 42 on opposites sides of the trench 52. Referring to FIG. 2B, after formation of the trench 52, p-type dopant ions 15 are implanted using angled implantation into sidewalls of the mesas 42 to form the sidewall gate regions 82 in the mesa sidewalls adjacent the trench 52.

Referring to FIG. 3, p-type dopant ions 17 are then implanted into the trench 52 using vertical (non-angled) ion implantation to form the gate contact region 76 at the base of the trench 52 that contacts the sidewall gate regions 82.

For vertical JFET devices having a narrow trench width/cell-pitch design, the angle for performing the implant of dopant ions 15 becomes acute, and it is difficult to implant the ions throughout the entire trench depth. Also, if the angle is low enough to get implanted ions to the bottom of the trench, the oxide mask 13 can scatter some ions, which may impact the performance of the device. Generally due to back-scattering from the trench bottom, the sidewall dose at the bottom region of the trench is higher than at the top region.

Also, when performing the vertical implant of dopant ions 17, the oxide mask 13 must have a thickness (vertical) sufficient to protect the source layer 60. If the oxide mask 13 is not thick enough, the source doping can be counter-doped, and the ohmic source resistance of the device can be undesirably increased. In a JFET device, source resistance is significant because of the very low drain-source on resistance (Rdson) needed for such devices.

Accordingly, the use of angled implants to form the sidewall gate regions 82 may result in the sidewall gate regions 82 having imprecise dimensions (e.g., thickness and/or length) and/or doping levels. Some embodiments provide vertical semiconductor devices having sidewall gate regions formed using epitaxially regrown layers. Epitaxial regrowth is a process used in semiconductor manufacturing in which a first crystalline layer is grown on a substrate. The first crystalline layer is then processed, such as by etching, implantation or other non-epitaxial growth process. A second crystalline layer is then “regrown” on the first crystalline layer. The dimensions and/or doping levels of sidewall gate regions formed using epitaxially regrown layers may be more precisely controlled than can be obtained using angled implants. For example, epitaxially regrown layers may be doped during the epitaxial growth process with precise dopant concentrations. Moreover, the epitaxial growth process may be controlled to obtain precise control of the thickness of the epitaxial layer.

To obtain better performance from a vertical JFET device, it is desirable to have a small cell-pitch for better specific on resistance (Ronsp) and to have a deep trench to obtain good blocking gain, where “blocking gain” refers to the difference between the threshold voltage at low and that at high drain-source voltage (V_{DS}).

To address two issues, some embodiments provide a new JFET structure having epitaxially grown junctions. This may provide a sharp N+-P+ gate junction, and may also help to control the doping level of the gate region irrespective of trench aspect ratio.

According to some embodiments, a trench etch is performed and the oxide mask used for the trench etch is removed. After cleaning the surface for epitaxial regrowth, a p-type layer is grown on all surfaces to form the gate region of the device. With this approach, epitaxial regrowth can be done with any aspect ratio of the trench and angled sidewall implants may be avoided.

Moreover, in previous approaches, an oxide mask 13 was needed to protect the source layer 60 when performing the vertical p-type gate implant (FIG. 3). Some embodiments may avoid the need for such a mask.

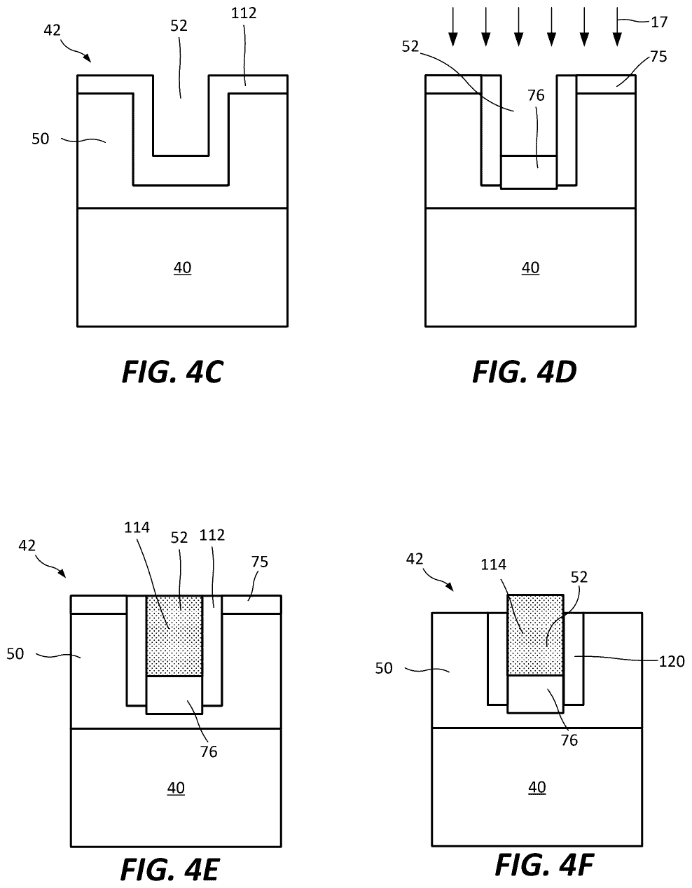

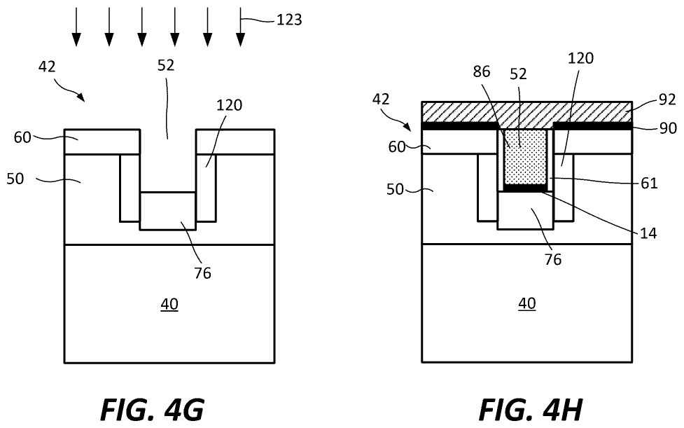

FIGS. 4A-4H illustrate operations for forming a vertical semiconductor device according to some embodiments. Referring to FIGS. 4A and 4B, a silicon carbide channel layer 50 is formed on a silicon carbide drift layer 40. The drift layer 40 is doped during epitaxial growth with n-type dopants at a first doping concentration that is typically less than about 1E17 cm−3. The channel layer 50 is doped during epitaxial growth with n-type dopants at a second doping concentration that is greater than the first doping concentration, typically greater than about 1E17 cm−3. A trench 52 is etched in the semiconductor layers 40, 50 to define respective mesas 42 on opposites sides of the trench 52.

Referring to FIG. 4C, after formation of the trench 52 and mesas 42, the structure is cleaned, and a silicon carbide semiconductor layer 112 is epitaxially re-grown on the structure. The semiconductor layer 112 is doped with p-type dopants and is grown to a thickness of about 0.1 microns to 2 microns. In some embodiments, the semiconductor layer 112 may be grown to a thickness of about 0.3 microns to 1.5 microns, and in some embodiments the semiconductor layer 112 may be grown to a thickness of about 0.5 microns to 1 micron.

The doping concentration of the semiconductor layer 112 may be about 1E18 cm−3 to 1E21 cm−3. In particular embodiments, the doping concentration of the semiconductor layer 112 may be about 5E18 cm−3 to 1E20 cm−3, and in further embodiments, the doping concentration of the semiconductor layer 112 may be about 1E19 cm−3.

The thickness and doping concentration of the semiconductor layer 112 are chosen based on the desired threshold voltage of the device, which is determined based on the doping concentration and thickness of the channel region. In particular, the product of the doping concentration and thickness of the layer may be greater than about 1E14 cm−2. For example, the product of the doping concentration and thickness of the layer may be between about 1E14 cm−2 and 1E16 cm−2, and in particular embodiments about 5E14 cm−2 to 5E15 cm−2.

As seen in FIG. 4C, the semiconductor layer 112 grows on sidewalls and top surfaces of the mesas 42 as well as on the bottom surface of the trench 52.

Referring to FIG. 4D, after the semiconductor layer 112 has been epitaxially re-grown, p-type dopant atoms 17 are implanted into the structure to form the gate contact region 76 at the bottom of the trench 52. Because the mesas 42 are not masked during this implant operation, highly doped p-type regions 75 are also formed on tops of the mesas 42 as a result of the implantation of the p-type dopant atoms 17.

Referring to FIG. 4E, a sacrificial dielectric layer 114 is then formed in the trench 52. The sacrificial dielectric layer 114 may be a material, such as silicon oxide, silicon nitride, or silicon oxynitride, that has an etch selectivity relative to silicon carbide.

Referring to FIG. 4F, the p-type semiconductor regions 75 are then removed from the upper portions of the mesas 42 via a dry etch process, such as a reactive ion etch or inductively coupled plasma etch process, or using a chemical-mechanical polish process, leaving the sacrificial dielectric layer 114 in place. The remaining portions of the regrown semiconductor layer 112 form sidewall gate regions 120.

Referring to FIG. 4G, n-type dopant ions 123 are implanted into the mesas 42 to form the source regions 60. Although not illustrated in FIG. 4G, a second implant step may be performed to form the highly doped source contact regions 38 shown in FIG. 1. the sacrificial dielectric layer 114 is then removed, for example via a wet etch process.

Referring to FIG. 4H, the remaining structure of the device is completed by forming sidewall spacers 61 on sidewalls of the mesas 42 facing the trench 52, metal silicide gate contacts 14 on the gate contact region 76, metal silicide source contacts 90 on the mesas 42, a dielectric layer 86 in the trench 52 and a source metallization 92 on the source contacts 90. Although not illustrated in FIG. 4H, metal gate fingers may be formed on the gate contacts 14.

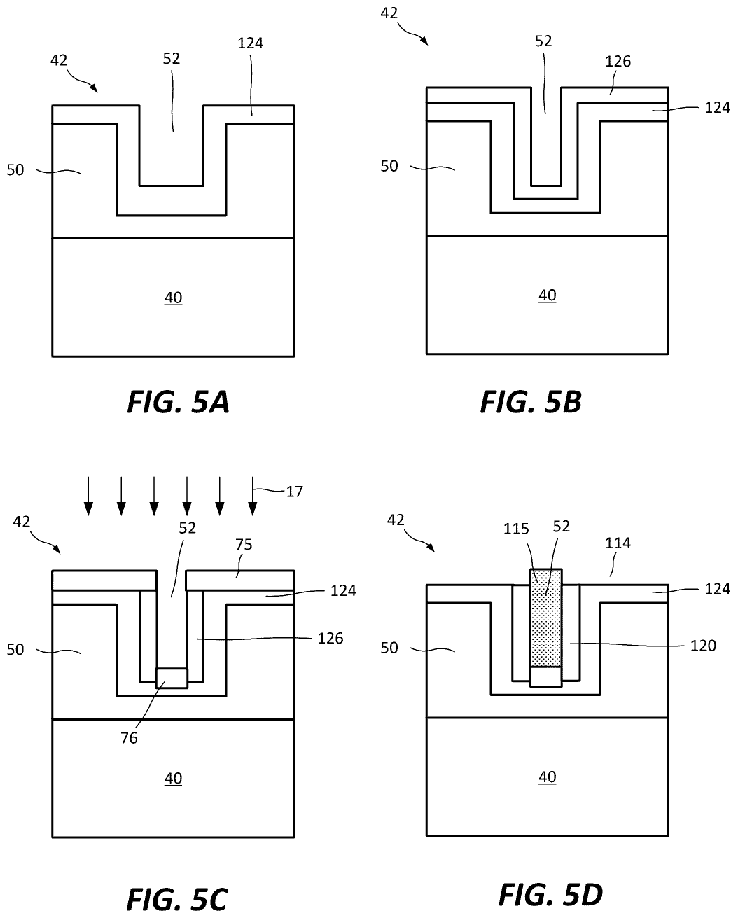

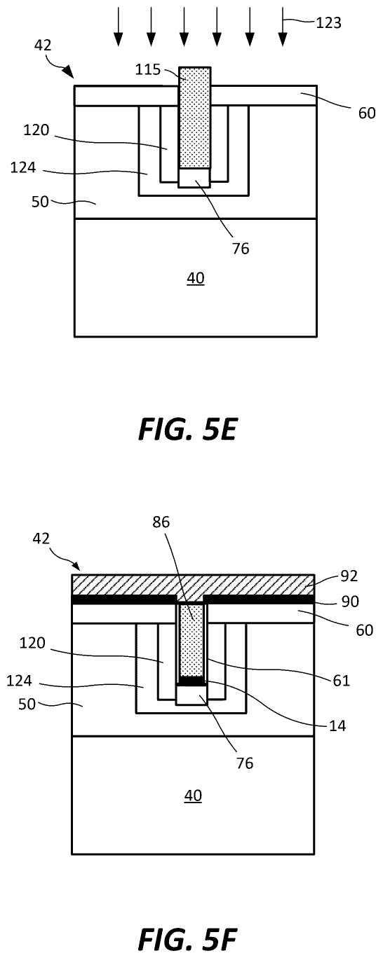

In some embodiments, source regions 60 and/or source contact regions 38 may be formed on the mesas 42 through epitaxial regrowth. For example, FIGS. 5A to 5F illustrate operations for forming a silicon carbide semiconductor device according to some embodiments.

Referring to FIG. 5A, an intermediate device structure is shown in which a trench 52 is formed. An n-type epitaxial layer 124 is epitaxially regrown on the structure. The n-type epitaxial layer 124 covers the mesas 42 as well as sidewalls and bottom of the trench 52.

The n-type epitaxial layer 124 may be formed to have a thickness of about 0.1 microns to 2 microns, and may have a doping concentration from about 1E19 cm−3 to 1E21 cm−3.

In some embodiments, the n-type epitaxial layer 124 may be grown to a thickness of about 0.3 microns to 1.5 microns, and in some embodiments the n-type epitaxial layer 124 may be grown to a thickness of about 0.5 microns to 1 micron.

In some embodiments, the doping concentration of the n-type epitaxial layer 124 may be about 5E19 cm−3 to 5E20 cm−3, and in further embodiments, the doping concentration of the n-type epitaxial layer 124 may be about 1E20 cm−3.

Referring to FIG. 5B, a p-type epitaxial layer 126 is then grown on top of the n-type epitaxial layer 124. The p-type epitaxial layer 126 also covers the mesas 42 as well as sidewalls and bottom of the trench 52.

The p-type epitaxial layer 126 is doped with p-type dopants and is grown to a thickness of about 0.1 microns to 2 microns. In some embodiments, the p-type epitaxial layer 126 may be grown to a thickness of about 0.3 microns to 1.5 microns, and in some embodiments the semiconductor layer 112 may be grown to a thickness of about 0.5 microns to 1 micron.

The doping concentration of the p-type epitaxial layer 126 may be about 1E18 cm−3 to 1E21 cm−3. In particular embodiments, the doping concentration of the p-type epitaxial layer 126 may be about 5E18 cm−3 to 1E20 cm−3, and in further embodiments, the doping concentration of the p-type epitaxial layer 126 may be about 1E19 cm−3.

Referring to FIG. 5C, p-type dopant ions 17 are then implanted into the structure to form a gate contact region 76 at the bottom of the trench 52. The implanted p-type dopant ions 17 also form heavily doped p-type regions 75 at the tops of the mesas 42.

Referring to FIG. 5D, a sacrificial dielectric layer 115 is then formed in the trench 52, and the p-type regions 75 at the tops of the mesas 42 are then removed, for example using a dry etch or chemical mechanical polish process, exposing the n-type epitaxial layer 124 and leaving remaining portions of the p-type epitaxial layer 126 as sidewall gate regions 120 on sidewalls of the trench 52.

Referring to FIG. 5E, n-type dopant ions 123 are then implanted into the structure to form source regions 60 at the upper portion of the mesas 42. Although not illustrated in FIG. 4F, a second implant step may be performed to form the highly doped source contact regions 38 on the source regions 60 shown in FIG. 1. The sacrificial dielectric layer 115 is then removed, for example using a wet etch process.

Referring to FIG. 5F, the remaining structure of the device is completed by forming sidewall spacers 61 on sidewalls of the mesas 42 facing the trench 52, gate contacts 14 on the gate contact region 76, source contacts 90 on the mesas 42, a dielectric layer 86 in the trench 52 and a source metallization 92 on the source contacts 90.

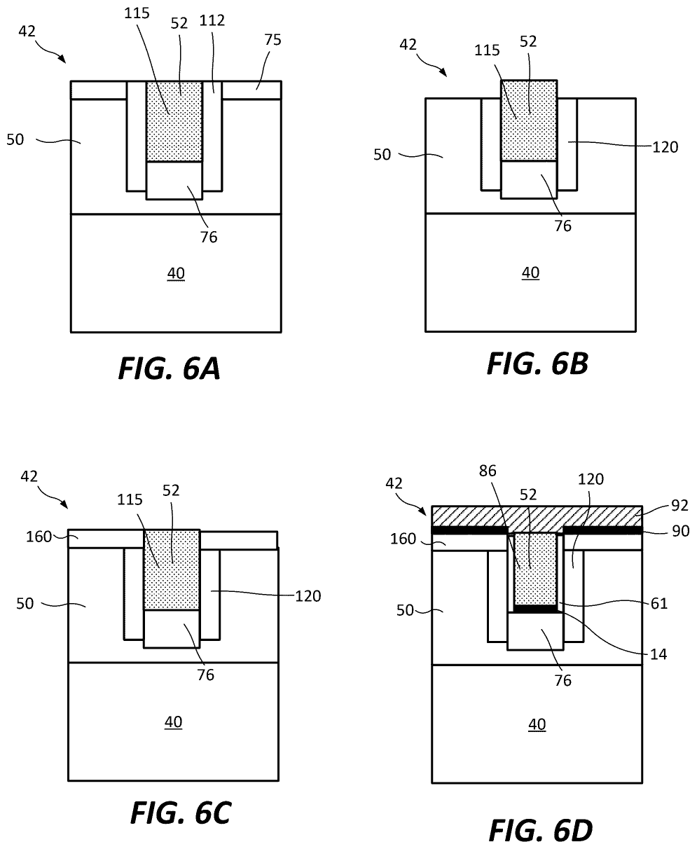

FIG. 6A to 6D illustrate operations for forming a silicon carbide semiconductor device according to further embodiments. Referring to FIG. 6A, an intermediate device structure is shown that includes highly doped p-type regions 75 that are formed on tops of the mesas 42 as a result of the implantation of the p-type dopant atoms 17 into the epitaxially regrown layer 112 to form the gate contact region 76 (as illustrated in FIG. 4D). A sacrificial dielectric layer 115 is then formed in the trench 52.

Referring to FIG. 6B, the highly doped p-type regions 75 are then removed, for example via a dry etch or chemical mechanical polish process, to expose the top surfaces of the channel layer 50, leaving the remaining portions of the epitaxially regrown layer 112 as sidewall gate regions 120.

Referring to FIG. 6C, source layer 160 is then formed on exposed top surfaces of the mesas 42 by epitaxial regrowth. The source layer 160 may be formed to have a thickness of about 0.1 microns to 2 microns, and may have a doping concentration from about 1E19 cm−3 to 1E21 cm−3.

In some embodiments, the source layer 160 may be grown to a thickness of about 0.3 microns to 1.5 microns, and in some embodiments the source layer 160 may be grown to a thickness of about 0.5 microns to 1 micron.

In some embodiments, the doping concentration of the source layer 160 may be about 5E19 cm−3 to 5E20 cm−3, and in further embodiments, the doping concentration of the source layer 160 may be about 1E20 cm−3.

Although not illustrated in FIG. 6C, a source contact layer 38 may be formed on the source layer 160 by epitaxial regrowth. Both the source layer 160 and the source contact layer 38 may be doped with n-type dopants, with the source contact layer 38 having a higher doping concentration than the source layer 160. The sacrificial dielectric layer 115 is then removed, for example by a wet etch process.

Referring to FIG. 6D, the remaining structure of the device is completed by forming sidewall spacers 61 on sidewalls of the mesas 42 facing the trench 52, gate contacts 14 on the gate contact region 76, source contacts 90 on the mesas 42, a dielectric layer 86 in the trench 52 and a source metallization 92 on the source contacts 90.

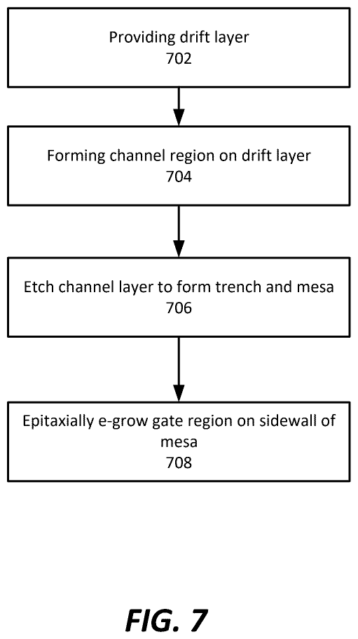

Operations according to some embodiments are illustrated in FIG. 7. In particular, a method of forming a silicon carbide semiconductor device includes providing a drift layer (block 702), and forming a channel layer on the drift layer (block 704). The channel layer has a first conductivity type. The method further includes etching the channel layer to form a trench in the channel layer and a mesa adjacent to the trench (block 706), and epitaxially regrowing a gate region on a sidewall of the mesa adjacent the trench (block 708). The gate region has a second conductivity type opposite the first conductivity type. Optionally, source layers may be formed on the mesas using epitaxial regrowth.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “in electrically conductive contact” means that two elements are in direct or indirect contact in such a way that electrical current can flow from one element to another. At least part of the connection between the two elements may be electrically resistive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A silicon carbide semiconductor device, comprising:
a drift layer;
a channel layer on the drift layer, the channel layer having a first conductivity type;
a trench in the channel layer and a mesa adjacent to the trench; and
a gate region within the trench, wherein the gate region has a second conductivity type opposite the first conductivity type, and wherein the gate region comprises an epitaxially regrown layer.

2. The silicon carbide semiconductor device of claim 1, further comprising:
a gate contact region in the channel layer beneath the trench, wherein the gate contact region has a second conductivity type opposite the first conductivity type, wherein the gate region is in contact with the gate contact region.

3. The silicon carbide semiconductor device of claim 2, further comprising:
a gate ohmic contact on the gate contact region; and
a dielectric spacer on a sidewall of the gate region facing the trench.

4. The silicon carbide semiconductor device of claim 1, wherein the gate region has a doping concentration of about 1E18 cm−3 to about 1E21 cm−3.

5. The silicon carbide semiconductor device of claim 1, wherein the gate region has a doping concentration of about 5E18 cm−3 to about 1E20 cm−3.

6. The silicon carbide semiconductor device of claim 1, wherein the gate region has a doping concentration of about 1E19 cm−3.

7. The silicon carbide semiconductor device of claim 1, wherein a product of a thickness of the gate region and a doping concentration of the gate region is about 1E14 cm−2 to 1E16 cm−2.

8. The silicon carbide semiconductor device of claim 1, wherein a product of a thickness of the gate region and a doping concentration of the gate region is greater than about 1E14 cm−2.

9. The silicon carbide semiconductor device of claim 1, wherein a product of a thickness of the gate region and a doping concentration of the gate region is about 5E14 cm−2 to 5E15 cm−2.

10. The silicon carbide semiconductor device of claim 1, wherein the gate region has a thickness of about 0.1 microns to 2 microns.

11. The silicon carbide semiconductor device of claim 1, wherein the gate region has a thickness of about 0.3 microns to 1.5 microns.

12. The silicon carbide semiconductor device of claim 1, wherein the gate region has a thickness of about 0.5 microns to 1 micron.

13. The silicon carbide semiconductor device of claim 1, wherein the silicon carbide semiconductor device comprises a junction field effect transistor device.

14. The silicon carbide semiconductor device of claim 1, further comprising a source layer in the mesa on the channel layer, wherein the source layer comprises an epitaxially regrown layer of silicon carbide.

15. The silicon carbide semiconductor device of claim 1, wherein the epitaxially regrown layer is on a sidewall of the trench.

16. A method of forming a silicon carbide semiconductor device, comprising:
providing a drift layer;
forming a channel layer on the drift layer, the channel layer having a first conductivity type;
etching the channel layer to form a trench in the channel layer and a mesa adjacent to the trench; and
epitaxially regrowing a gate region within the trench, wherein the gate region has a second conductivity type opposite the first conductivity type.

17. The method of claim 16, wherein the gate region is on a sidewall of the trench.

18. The method of claim 17, further comprising:
after epitaxially regrowing the gate region, implanting second conductivity type dopant ions into the trench to form a gate contact region beneath the trench, wherein the gate contact region contacts the gate region.

19. The method of claim 18, wherein the second conductivity type dopant ions are implanted into the mesa and the trench, the method further comprising:
after implanting the second conductivity type dopant ions, etching a top portion of the mesa.

20. The method of claim 19, further comprising:
after implanting the second conductivity type dopant ions, depositing an oxide layer in the trench, and planarizing the oxide layer.

21. The method of claim 19, further comprising:
after etching the top portion of the mesa, implanting second conductivity type ions into the mesa.

22. The method of claim 19, further comprising epitaxially regrowing a source layer on the channel layer.

23. A silicon carbide semiconductor device, comprising:
a silicon carbide layer comprising a trench therein; and
an epitaxially regrown region within the trench.

24. The silicon carbide semiconductor device of claim 23, wherein the epitaxially regrown region comprises a gate region on a sidewall of the trench.

25. The silicon carbide semiconductor device of claim 24, wherein the silicon carbide layer comprises a drift layer, a channel layer on the drift layer and a source layer on the channel layer, wherein the drift layer, the channel layer and the source layer have a first conductivity type and the gate region has a second conductivity type opposite the first conductivity type.

26. The silicon carbide semiconductor device of claim 25, wherein the source layer comprises an epitaxially regrown layer.

27. A silicon carbide semiconductor device, comprising:
a drift layer;
a channel layer on the drift layer, the channel layer having a first conductivity type;
a trench in the channel layer and a mesa adjacent to the trench;
a gate region within the trench, wherein the gate region has a second conductivity type opposite the first conductivity type, and wherein the gate region comprises an epitaxially regrown layer; and
a source layer on the channel layer, wherein the source layer has the first conductivity type and comprises an epitaxially regrown layer.

28. The silicon carbide semiconductor device of claim 27, wherein a product of a thickness of the gate region and a doping concentration of the gate region is greater than about 1E14 cm−2.

29. The silicon carbide semiconductor device of claim 27, wherein a product of a thickness of the gate region and a doping concentration of the gate region is about 5E14 cm−2 to 5E15 cm−2.

30. The silicon carbide semiconductor device of claim 27, wherein the gate region has a thickness of about 0.1 microns to 2 microns.

31. A method of forming a silicon carbide semiconductor device, comprising:
providing a drift layer;
forming a channel layer on the drift layer, the channel layer having a first conductivity type;
etching the channel layer to form a trench in the channel layer and a mesa adjacent to the trench;
epitaxially regrowing a first semiconductor layer in the trench and on an upper surface of the mesa, the first layer having the first conductivity type; and
epitaxially regrowing a second semiconductor layer on the first layer, the second layer having a second conductivity type opposite the first conductivity type.

32. The method of claim 31, further comprising:
after epitaxially regrowing the second semiconductor layer, removing portions of the second semiconductor layer from the upper surface of the mesa.

33. The method of claim 32, further comprising:
forming a sacrificial dielectric layer in the trench; and
implanting first conductivity type dopant ions into the mesa to form a source region in the mesa.

34. The method of claim 31, further comprising:
after epitaxially regrowing the second semiconductor layer, implanting second conductivity type dopant ions into the trench to form a gate contact region in the trench.

35. A silicon carbide semiconductor device, comprising:
a drift layer;
a channel layer on the drift layer, the channel layer having a first conductivity type;
a trench in the channel layer and a mesa adjacent to the trench;
a first epitaxially regrown region in the trench, the first epitaxially regrown region having a first conductivity type; and
a second epitaxially regrown region on the first epitaxially regrown region, the second epitaxially regrown region having a second conductivity type opposite the first conductivity type.

36. The silicon carbide semiconductor device of claim 35, further comprising:
a gate contact region in the channel layer beneath the trench, wherein the gate contact region has the second conductivity type, wherein the gate region is in contact with the second epitaxially regrown region.

37. The silicon carbide semiconductor device of claim 36, further comprising:
a gate ohmic contact on the gate contact region; and
a dielectric spacer on a sidewall of the second epitaxially regrown region facing the trench.
